(19) United States
(12) Patent Application Publication
(10) Pub. No.: US 2010/0284149 A1
(43) Pub. Date: Nov. 11, 2010

(54) POWER SUPPLY AND A HOUSING STRUCTURE WITH THE POWER SUPPLY

(75) Inventor: YEN-WEN SU, Taoyuan City (TW)

Correspondence Address: KILE PARK REED & MCMANUS, 1200 NEW HAMPSHIRE AVE, NW, SUITE 570, WASHINGTON, DC, 20036, US

(73) Assignee: Enermax Technology Corporation

(21) Appl. No.: 12/435,583

(22) Filed: May 5, 2009

(51) Int. Cl. H05K 7/20

(52) U.S. Cl. 361/695

(57) ABSTRACT

A power supply and a housing structure with the power supply are disclosed. The power supply includes a power supply housing, a cooling fan, a circuit structure, and a plurality of lighting elements. One side of the power supply housing has a first wall, and the first wall has air inlet holes. Another side of the power supply housing has a second wall, and the second wall has air outlet holes. The cooling fan is located in the power supply housing and corresponds to the air inlet holes. The circuit structure is combined with the first wall and adjacent to the air inlet holes. The lighting elements are located at one side of the circuit structure to emit light to outside of the power supply housing. When the housing structure is installed with the power supply, the housing structure has a function of illuminating the interior of the housing structure.

### BACKGROUND OF THE INVENTION

1. Field of the Invention

The present invention relates to a power supply and a housing structure with the power supply; in particular, the present invention relates to a power supply that utilizes a circuit structure so as to combine a plurality of lighting elements to emit light beams to outside the power supply housing and a housing structure with the power supply.

2. Description of Related Art

The commonization of computers has been revolutionary for people's life style. Therein, a power supply is generally installed in each computer in order to provide the required power for operating various electronic devices inside the computer. The power supply usually has a cooling fan to exhaust heat generated by the power supply, and to prevent the power supply from being damaged due to excessively high temperature.

However, the appearance of a conventional power supply is simple, and merely has the cooling effect. When the conventional power supply is installed in the computer, it lacks a sense of aesthetic beauty and visible effect. Moreover, some of the conventional power supply has been progressing towards multi-functional design, therefore is inadequate for a power supply to merely having the power supply function. If a lighting function is added to the power supply, the function of the power supply will be more versatile.

### SUMMARY OF THE INVENTION

One particular aspect of the present invention is to provide a power supply. The housing of the power supply has a circuit structure and lighting elements so that the power supply can emit light.

Another particular aspect of the present invention is to provide a housing structure with a power supply. The housing structure uses the light emitted from the power supply that is located within the housing structure, so as to provide a lighting function for the components in the housing structure.

The power supply has a power supply housing, a cooling fan, a circuit structure, and a plurality of lighting elements. One side of the power supply housing has a first wall, and the first wall has a plurality of air inlet holes. Another side of the power supply housing has a second wall, and the second wall has a plurality of air outlet holes. The cooling fan is located in the power supply housing and corresponds to the air inlet holes. The circuit structure is combined with the first wall and is adjacent to the air inlet holes. The lighting elements are located at one side of the circuit structure to emit light to outside of the power supply housing.

The housing structure with a power supply includes a housing body and a power supply located in the housing body. The power supply includes a power supply housing, a cooling fan, a circuit structure, and a plurality of lighting elements. One side of the power supply housing has a first wall, and the first wall has a plurality of air inlet holes. Another side of the power supply housing has a second wall, and the second wall has a plurality of air outlet holes. The cooling fan is located in the power supply housing and corresponds to the air inlet holes. The circuit structure is combined with the first wall and is located around the air inlet holes. The lighting elements are located at one side of the circuit structure to emit light to outside of the power supply housing.

The present invention has the following characteristics.

1. Because a plurality of lighting elements is located on the power supply housing, the power supply of the present invention has the lighting function. By utilizing the lighting elements, the sense of aesthetic beauty and visible effect is enhanced. The appearance of the power supply is unique, and the function of the power supply is versatile.

2. By having the air inlet holes cooperating with the cooling fan, the power supply of the present invention can efficiently cool the lighting elements.

3. By utilizing the lighting elements located on the power supply, the housing structure of the present invention provides the lighting function so that the user can see the operation status of the electronic elements in the housing body.

For further understanding of the present invention, reference is made to the following detailed description illustrating the embodiments and examples of the present invention. The description is for illustrative purpose only and is not intended to limit the scope of the claim.

### BRIEF DESCRIPTION OF THE DRAWINGS

FIG. 1 is an assembly perspective view of a power supply according to the first embodiment of the present invention;

FIG. 2 is an exploded perspective view of the power supply according to the first embodiment of the present invention;

FIG. 3 is an exploded perspective view of the power supply according to the second embodiment of the present invention, wherein the base is omitted;

FIG. 4 is a side view of a housing structure with the power supply of the present invention.

### DETAILED DESCRIPTION OF THE PREFERRED EMBODIMENTS

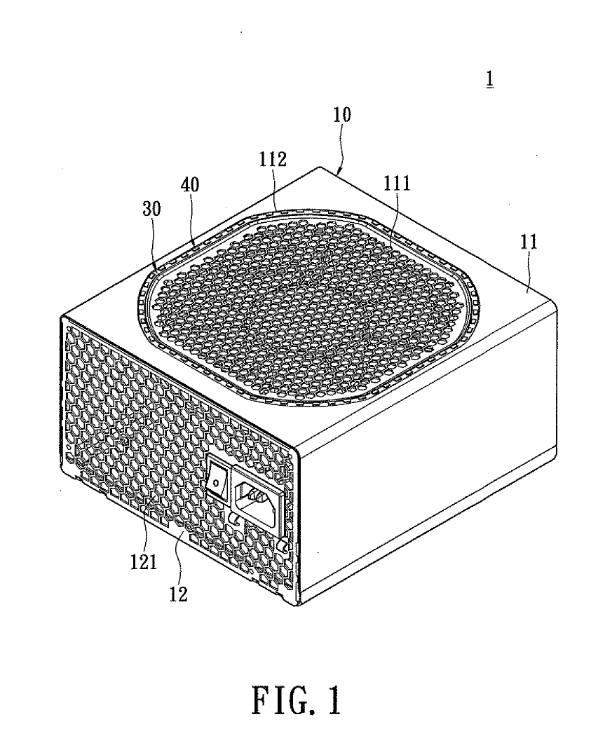

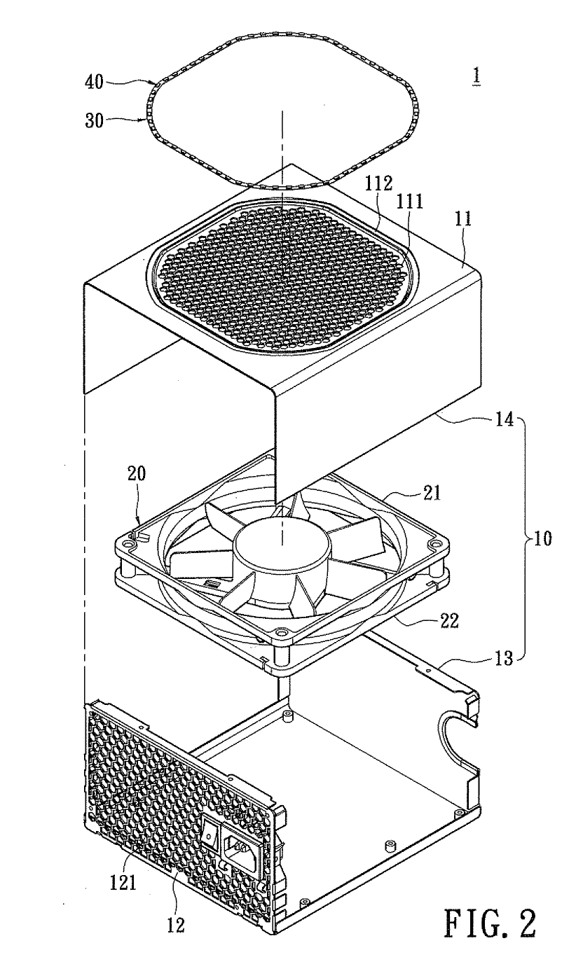

Reference is made to FIGS. 1 and 2, which shows the power supply 1 according to the first embodiment of the present invention. The power supply 1 includes a power supply housing 10, a cooling fan 20, a circuit structure 30, and a plurality of lighting elements 40.

The shape of the power supply housing 10 is rectangular. One side of the power supply housing 10 has a first wall 11, and the first wall 111 has a plurality of air inlet holes 111. Another side of the power supply housing 110 has a second wall 12, and the second wall 12 has a plurality of air outlet holes 121.

The air inlet holes 11 may be integrated with the first wall 11 as one integral piece for achieving the effect of air flow, but not specifically limited thereby. Alternatively, the first wall 11 may have a through hole (not shown in the figure), and a component with a plurality of air inlet holes 111 is assembled around the through hole of the first wall 11 (such as a fan protection screen) so as to achieve the same effect. In this embodiment, the structure of the power supply housing 10 is a two-piece structure, but the present invention is not limited thereby. The power supply housing 10 includes a base 13 and a cover body 14. The cover body 14 matches the base 13 to form a power supply housing 10 that is enclosed.

The cooling fan 20 has an air inlet end 21 and an air outlet end 22; wherein the air inlet end 21 corresponds to the air inlet hole 111 of the power supply housing 10, and the air outlet end 22 is located opposite to the air inlet end 21. The cooling fan 20 draws air from outside of the power supply housing 10 via the air inlet end 21 and blows air to the electronic elements (not shown in the figure) in the power supply housing 10 via the air outlet end 22, so as to achieve the cooling effect. The cooling fan 20 is located in the power supply housing 10 and corresponds to the air inlet holes 111.

The circuit structure 30 is combined with the first wall 11 and is adjacent to the air inlet holes 111. The shape of the circuit structure 30 can be rectangular or circular, but the present invention is not limited thereby. In the present embodiment, the circuit structure 30 is located around the air inlet holes 111 and encircles to form a ring. The circuit structure 30 can be combined with the first wall 11 by pasting, screw elements, or wedging, but the present invention is not limited thereby.

Alternatively, the surface of the first wall 11 further has a concave trough 112 (as shown in FIG. 2) for receiving the circuit structure 30. The shape of the concave trough 112 matches the outline of the circuit structure 30 so that the circuit structure 30 can be easily assembled and positioned.

The lighting elements 40 can be LEDs or other lighting elements with different types, but the present invention is not limited thereby. The color of the light from the lighting elements 40 also is not limited to a specific one. In this embodiment, the lighting elements 40 are surface mount type LEDs. The lighting elements 40 are located at one side of the circuit structure 30, and are respectively and electrically connected with the circuit structure 30; furthermore the lighting elements 40 are disposed in a ring formation. The lighting elements 40 respectively emit light to outside of the power supply housing 10.

When the power supply 1 is turned on, air is drawn into the power supply housing 10 via the air inlet holes 111 from outside of the power supply housing 10 through the rotation of the cooling fan 20, and air is exhausted via the air outlet holes 121 to exhaust heat that has been generated in the power supply housing 10. At this time, the lighting elements 40 emit light to outside of the power supply housing 10 and the light beam forms a ring of light around the air inlet holes 111 and upon the surface of the power supply housing 10. Thereby, a sense of aesthetic beauty and visible effect is produced.

Moreover, because the lighting elements 40 are adjacent to the air inlet holes 111, heat generated from the lighting elements 40 can also be exhausted via the cooling fan 20 through the air inlet holes 111 and air outlet holes 121 as aforementioned.

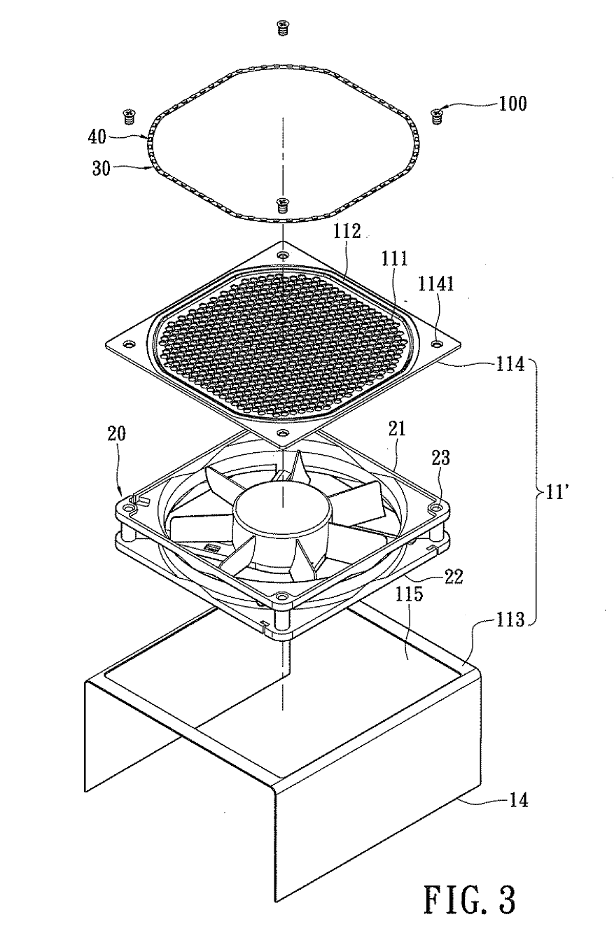

Reference is made to FIG. 3, which shows the power supply according to the second embodiment of the present invention. The difference between the second embodiment and the first embodiment is:

The first wall 11′ of the power supply housing 10 includes a base portion 113 and a separating portion 114 that is combined with the base portion 113, wherein the base portion 113 and the separating portion 114 can be assembled and disassembled. The base portion 113 has an opening 115 for receiving the separating portion 114. The corners of the separating portion 114 has a plurality of through holes 1141 that correspond to the fastening holes 23 of the cooling fan 20 for being plugged by screws 100. Thereby, the cooling fan 20 is located on the separating portion 114.

In this embodiment the air inlet holes 111 are located on the separating portion 114, and the circuit structure 30 is combined with the separating portion 114. The separating portion 114 further has a concave trough 112 for receiving the circuit structure 30.

In this embodiment, because the separating portion 114 can be directly disassembled from outside of the power supply housing 10, it is easy to replace and substitute another separating portion 114 having lighting elements 40 of different color, so as to change the lighting color of the power supply 1. Furthermore, because the cooling fan 20 is combined with the separating portion 114, the cooling fan 20 also can be disassembled when the separating portion 114 is disassembled. Therefore, the cooling fan 20 can be easily and rapidly replaced.

In this embodiment, the circuit structure 30 is a flexible printed circuit board, but the present invention is not limited thereby. Because the flexible printed circuit board is flexible and can be easily added with circuits to increase the quantity of the lighting elements 40, the lighting elements 40 can be controlled to generate a versatile lighting effect. By using the flexible printed circuit board, the lighting functions can be easily enhanced.

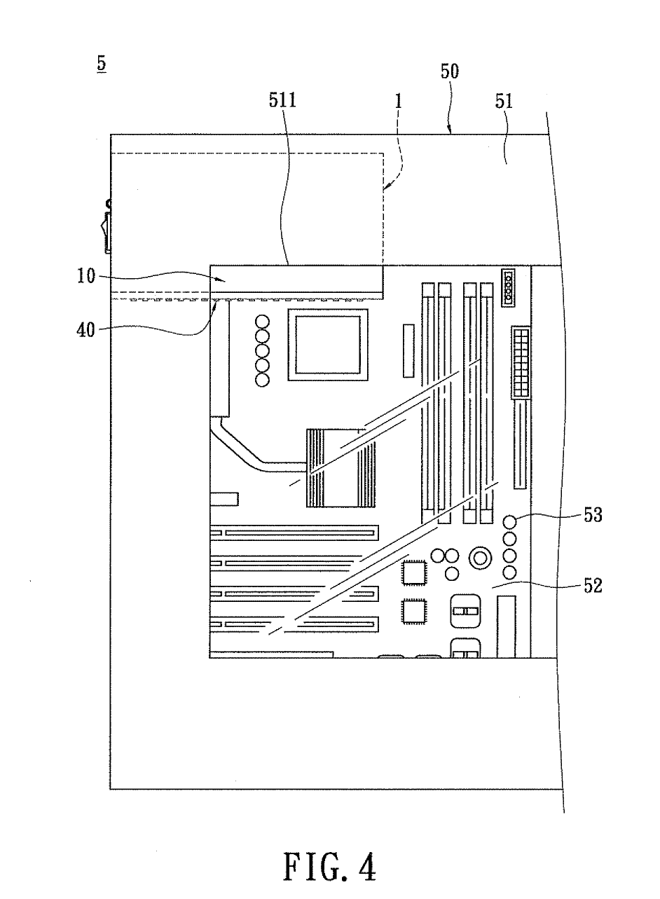

Moreover, the circuit structure 30 can also be other structure with circuit. For example, a circuit is located in a flexible transparent structure (such as a sleeve tube) and is electrically connected with the lighting elements 40. Alternatively, the circuit structure 30 can be a circuit structure that includes a circuit and has a fixed shape to achieve the lighting effect, such as a lamp. Reference is made to FIGS. 4, and 1-3. The power supply 1 can also be located in a housing body 50 to form a housing structure 5. In the figure, the power supply 1 is located in the housing body 50 and is close to the top of the hosing body 50. Alternatively, the power supply 1 is located in the housing body 50 and is close to the bottom of the housing body 50 (not shown in the figure).

One side of the housing body 50 has a side board 51 and a transparent covering part 52. The center of the side board 51 has a hollow portion 511 that has a large dimension.

The transparent covering part 52 is a transparent board body, and is located at the inner side of the side board 51. The transparent covering part 52 is used for covering the hollow portion 511. Because the transparent covering part 52 is transparent, the user can easily see the interior of the housing body 50.

Alternatively, the side board 51 can be directly made of transparent material to omit the hollow portion 511 and the transparent covering part 52 and still achieve the same effect of easily viewing the interior of the housing body 50.

When the housing structure 5 is used, the light beam emitted from the lighting elements 40 of the power supply 1 provides the lighting function for the interior of the housing body 50. The user can check the interior of the housing body 50 via the hollow portion 511 of the side board 51 to see the operation status of the electronic elements 53 in the housing body 50. At the same time, by utilizing the cooling fan 20 of the power supply 1, the heat generated by the lighting elements 40 can be exhausted.

The present invention has the following characteristics.

1. The power supply 1 of the present invention disposes a plurality of lighting elements 40 on the power supply housing 10. The lighting elements 40 are close to the air inlet holes 111 and emit light to outside of the power supply housing 10. Thereby, the power supply 1 has the lighting function, and the sense of aesthetic beauty and visible effect is improved and thus results in a unique appearance. The functions of the power supply are thereby enhanced.

2. By having the air inlet holes 111 cooperating with the cooling fan 20, the power supply 1 of the present invention can exhaust heat generated from the lighting elements 40.

3. The housing structure 5 of the present invention has a power supply 1 in the housing body 50. By using the lighting function of the lighting elements 40 located in the power supply housing 10, the user can see the operation status of the electronic elements 53 in the housing body 50.

The description above only illustrates specific embodiments and examples of the present invention. The present invention should therefore cover various modifications and variations made to the herein-described structure and operations of the present invention, provided that they fall within the scope of the present invention as defined in the following appended claims.

What is claimed is:

1. A power supply, comprising:
a power supply housing, wherein one side of the power supply housing has a first wall, the first wall has a plurality of air inlet holes, another side of the power supply housing has a second wall, and the second wall has a plurality of air outlet holes;
a cooling fan located in the power supply housing, wherein the cooling fan corresponds to the air inlet holes;
a circuit structure combined with the first wall and adjacent to the air inlet holes, and
a plurality of lighting elements located at one side of the circuit structure to emit light to outside of the power supply housing.

2. The power supply as claimed in claim 1, wherein the circuit structure is a flexible printed circuit board.

3. The power supply as claimed in claim 1, wherein the lighting element is a surface mount type LED.

4. The power supply as claimed in claim 1, wherein the circuit structure is located around the air inlet holes.

5. The power supply as claimed in claim 1, wherein the first wall includes a base portion and a separating portion that is combined with the base portion and can be disassembled, the air inlet holes and the cooling fan are located on the separating portion, and the circuit structure is combined with the separating portion.

6. The power supply as claimed in claim 5, wherein the base portion has an opening, and the separating portion is located on the opening.

7. A housing structure with a power supply, comprising:
a housing body; and
a power supply located in the housing body, wherein the power supply comprises:
a power supply housing, wherein one side of the power supply housing has a first wall, the first wall has a plurality of air inlet holes, another side of the power supply housing has a second wall, and the second wall has a plurality of air outlet holes;
a cooling fan located in the power supply housing, wherein the cooling fan corresponds to the air inlet holes;
a circuit structure combined with the first wall and located around the air inlet holes, and
a plurality of lighting elements located at one side of the circuit structure to emit light to outside of the power supply housing.

8. The housing structure with a power supply as claimed in claim 7, wherein one side of the housing body has a side board and a transparent covering part, the side board has a hollow portion, and the transparent covering part covers the hollow portion.

9. The housing structure with a power supply as claimed in claim 7, wherein one side of the housing body has a side board that is made of transparent material.

10. The housing structure with a power supply as claimed in claim 7, wherein the circuit structure is a flexible printed circuit board.

11. The housing structure with a power supply as claimed in claim 7, wherein the first wall includes a base portion and a separating portion that is combined with the base portion and can be disassembled, the air inlet holes and the cooling fan are located on the separating portion, and the circuit structure is combined with the separating portion.

12. The housing structure with a power supply as claimed in claim 11, wherein the base portion has an opening, and the separating portion is located on the opening.

13. The housing structure with a power supply as claimed in claim 7, wherein the lighting element is a surface mount type LED.

14. The housing structure with a power supply as claimed in claim 7, wherein the circuit structure is located around the air inlet holes.
